(19) United States
(12) Patent Application Publication
(10) Pub. No.: US 2005/0258483 A1
(43) Pub. Date: Nov. 24, 2005

(54) Quasi-vertical power semiconductor device on a composite substrate

(75) Inventors: Francois Templier, Voiron (FR); Lea Di Cioccio, Saint Ismier (FR); Thierry Billon, Coublevie (FR); Fabrice Letertre, Jongkind, Grenoble (FR)

Correspondence Address: Thelen Reid & Priest, P O Box 640640, San Jose, CA, 95164-0640, US

(73) Assignee: Commissariat a l'ENERGIE ATOMIQUE, PARIS (FR)

(21) Appl. No.: 10/526,641

(22) PCT Filed: Sep. 1, 2003
(86) PCT No.: PCT/FR03/50045

§ 371 Date: Mar. 2, 2005

(30) Foreign Application Priority Data
Sep. 3, 2002 (FR) 02/10883

(51) Int. Cl. H01L 29/76

(52) U.S. Cl. 257/341

(57) ABSTRACT

The invention relates to a power semiconducting device made from a semiconducting material epitaxied on a stacked structure (10) comprising a layer of semiconducting material (13) transferred onto a first face of a support substrate (11) and fixed to the support substrate by an electrically insulating layer (12), the support substrate comprising electrically conducting means between said first face and a second face, the transferred layer of semiconducting material (13) acting as an epitaxy support for the epitaxied semiconducting material (14, 15). Means (16, 17) of electrically connecting the device are provided, firstly on the epitaxied semiconducting material, and secondly on the second face of the support substrate, an electrical connection through the electrically insulating layer and said electrically conducting means of the support substrate electrically connecting the epitaxied semiconducting material (14, 15) to the electrically connecting means (17) provided on the second face of the support substrate (11).

### TECHNICAL FIELD

The present invention relates to a quasi-vertical power semiconducting device on a composite substrate.

### STATE OF PRIOR ART

Systems for manufacturing SiC-based power devices are currently made on solid monocrystalline SiC substrates with polytype 4H and with a low bulk electrical resistivity. This type of substrate can be used for manufacturing electronic devices, for example of the Schottky diode, PIN diode or MOS, JFET or MESFET transistor type, components that use a vertical transfer of electrical current between the front face and the back face of this substrate during their operation.

FIG. 1 shows a cross sectional view of such a power semiconducting device. It is actually a Schottky diode. The diode is made from an n⁺ type solid SiC substrate 1 on which two SiC layers 2 and 3 have been epitaxied, one after the other. Layer 2 is n+doped and layer 3 is n⁻ doped. The back face of the substrate 1 is metallised to give resistive contact 4. A metallic stud 5 is deposited on layer 3 to make a Schottky contact. A local implantation of layer 3 provides a p type zone 6 providing peripheral protection.

This vertical design of the device is particularly suitable for discrete components that, after collective fabrication on a complete monocrystalline SiC wafer, are separated from each other by cutting out chips. The electrical connection between these chips and the package is made in a standard manner by making contact between the front and back faces in the same way as for discrete silicon components.

The advantages of the “solid substrate” system lie in the vertical structure of the device (ease of input of strong currents and assembly in a package similar to the silicon standard) and in the fact that the substrate enables homoepitaxy of SiC. The disadvantages of this system are its cost, the small diameter of substrates, their poor availability and the impossibility of integrating components in a system approach.

An alternative substrate method for the above mentioned applications is to use composite substrates comprising a thin semiconducting layer bonded on a substrate and obtained using the Smart-Cut® process. This process is described in document FR-A-2 681 472 (corresponding to U.S. Pat. No. 5,374,564). The thin layer and the initial substrate may be made of different materials due to the complete freedom provided by this process for making composite substrates. Some of the possibilities of this process include making SiCOI (“SiC On Insulator”) substrates composed of a thin layer of SiC bonded onto a substrate. that appears to be electrically insulating from the thin layer, for example like an oxidised silicon substrate. The monocrystalline SiC layer is less than 1 μm thick, typically 0.5 μm. This SiCOI structure provides a means of making electrical components using the thin transferred layer as the active layer. In this case, the electronic components are confined in this very thin layer with its inherent advantages and disadvantages. The advantages are the simplicity of the manufacturing process and the fact that integrated circuits can be made, since the components are isolated. This system has the following disadvantages. Since the electrical contacts project from the same face of the component, they cannot be integrated into standard silicon packages. Since the film is thin, it limits component performances in terms of current passing in the thin film.

The technical problem that arises is to be able to make electronic components on a Smart-Cut type composite substrate, with electronic performances (particularly in terms of current) at least equivalent to performances conventionally obtained on fully monocrystalline substrates. Furthermore, part of the problem is to be able to make power components electrically insulated from each other on the same structure, one of them possibly being electrically connected to the composite stack support substrate.

### SUMMARY OF THE INVENTION

In order to overcome the disadvantages of prior art, an electronic device with vertical conduction is proposed made on a semiconductor-on-insulator type composite substrate comprising two electrical contacts made on the front face with an electrical connection of one of the contacts to an electrically conducting support substrate, after opening the insulating layer. This provides a means of benefiting from the advantages of semiconductor-on-insulator type composite substrates while using a conventional package type assembly.

The invention has the following advantages:
the possibility of having a large support substrate less expensive than a solid SiC substrate,
the possibility of using a quasi-vertical structure of the devices to achieve equivalent or better current densities than are possible on a solid substrate,
the possibility of having a conventional package with connections at the front and the other face at the back (case of diodes),
the possibility of having a simpler manufacturing process (only one metal for a resistive contact and Schottky contact),
the possibility of designing integrated power systems benefiting from a natural galvanic isolation when the thin layer is bonded onto a support through an electrical insulating layer (for example silicon dioxide and nitride),
the possibility of being able to electrically connect a component to the substrate present under the electronic insulation layer.

Therefore, the purpose of the invention is a power semiconducting device made from a semiconducting material epitaxied on a stacked structure, characterised in that:
the stacked structure comprises a layer of semiconducting material transferred onto a first face of a support substrate and fixed to the support substrate by an electrically insulating layer, the support substrate comprising electrically conducting means between said first face and a second face, the transferred layer of semiconducting material acting as an epitaxy support for the epitaxied semiconducting material,
means of electrically connecting the device are provided, firstly on the epitaxied semiconducting material, and secondly on the second face of the support substrate, an electrical connection through the electrically insulating layer and said electrically conducting means of the support substrate electrically connecting the epitaxied semiconducting material to the electrically connecting means provided on the second face of the support substrate.

Advantageously, the electrically conducting means of the support are composed of the support substrate itself made of an electrically conducting material.

The epitaxied semiconducting material may comprise several layers with a different doping.

The support substrate may be overdoped on the side of the interface on which the electrically insulating layer is provided.

The electrically conducting means of the device may comprise at least one Schottky contact and/or at least one resistive contact.

Advantageously, the support substrate is made from a semiconducting material chosen for example from among SiC, GaN, AlN, Si, GaAs, ZnO and Ge.

The material used to make the electrically conducting layer may be chosen from among SiO₂, Si₃N₄ and diamond.

The transferred thin layer of semiconducting material may be made from a material chosen from among SiC, GaN, AlN, Si, ZnO and diamond.

The epitaxied semiconducting material may be chosen from among SiC, GaN, AlGaN, InGaN and diamond.

Another purpose of the invention is a semiconducting circuit, characterised in that it combines at least one power semiconducting device like that defined above and at least one semiconducting device that is not electrically connected to the second face of the support substrate, on the same stacked structure.

### BRIEF DESCRIPTION OF THE DRAWINGS

The invention will be better understood and other advantages and special features will become clear after reading the following description given as a non-limitative example accompanied by the appended drawings, wherein:

FIG. 1 described above is a cross-sectional view of a power semiconducting device according to prior art,

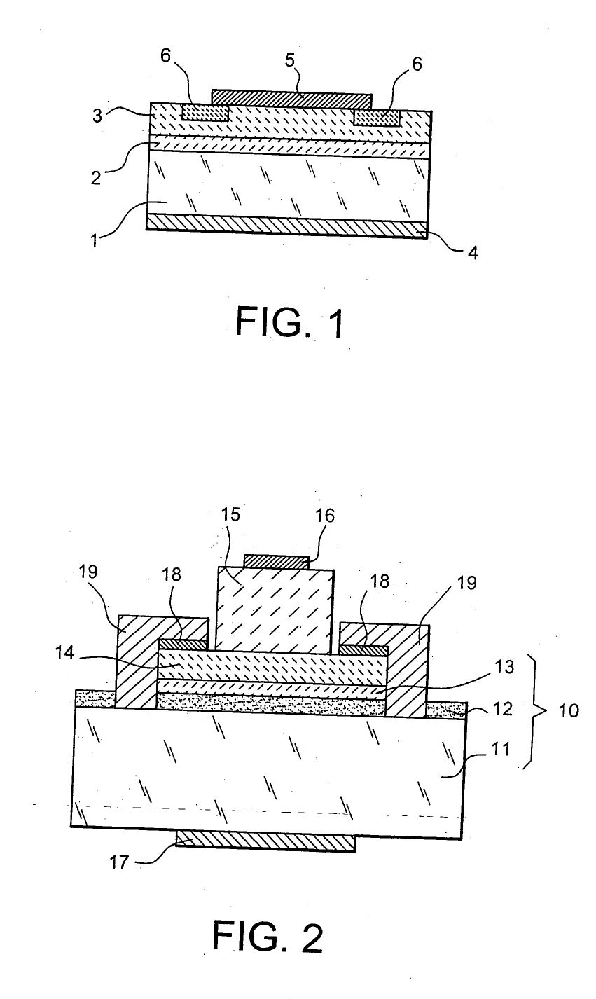

FIG. 2 is a cross-sectional view of a power semiconducting device according to the invention,

FIGS. 3A to 3J are cross-sectional views illustrating a process for making a power semiconducting device according to the invention,

FIG. 4 is a cross-sectional view of another power semiconducting device according to the invention,

FIG. 5 is a cross-sectional view of a semiconducting device that can be associated with a power semiconducting device according to the invention in order to make an integrated circuit.

### DETAILED DESCRIPTION OF EMBODIMENTS OF THE INVENTION

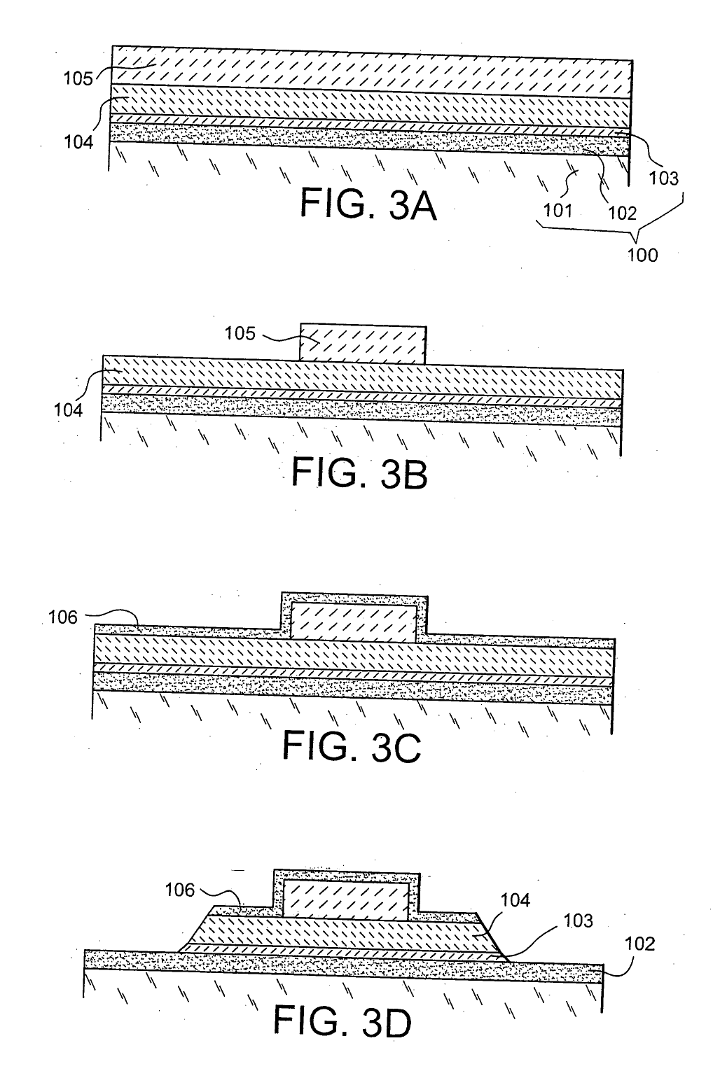

FIG. 2 shows a cross-sectional view of a power semiconducting device according to the invention. The device is made on the front face of a composite substrate 10. In this example, the support substrate 11 is made of silicon and supports a silicon dioxide layer 12 and a layer of SiC 13, transferred on the support substrate 11 for example using the Smart-Cut® process and fixed to this support substrate by the silicon dioxide layer 12.

The transferred SiC layer 13 is used as an epitaxy support for the n⁺ doped SiC layer 14 and for the n⁻ doped SiC layer 15.

The inventors of this invention have succeeded in making SiC epitaxies on this composite substrate in an unexpected manner. Silicon dioxide does not deteriorate at epitaxy temperatures slightly lower than the melting temperature of silicon and the quality of the epitaxies obtained is good, comparable to epitaxies on solid SiC.

The metal for which the interface with the contact semiconducting material is a Schottky contact or a resistive contact may inaccurately be called a Schottky contact or a resistive contact.

The device also comprises a Schottky contact 16 arranged on the SiC layer 15 and a resistive contact 17 arranged on the back face of the support substrate 11. Resistive contacts 18 are arranged on the top face of the SiC layer 14. They enable an electrical connection between the SiC layer 14 and the resistive contact 17 on the back face using metallisations 19 deposited on the resistive contacts 18, coming into contact with the support substrate 11 through the silicon dioxide layer 12, and due to the support substrate 11 that is sufficiently conducting. Furthermore, the contact between metallisations 19 and the support substrate 11 is a resistive contact. Therefore, this power device can be qualified as a quasi-vertical device.

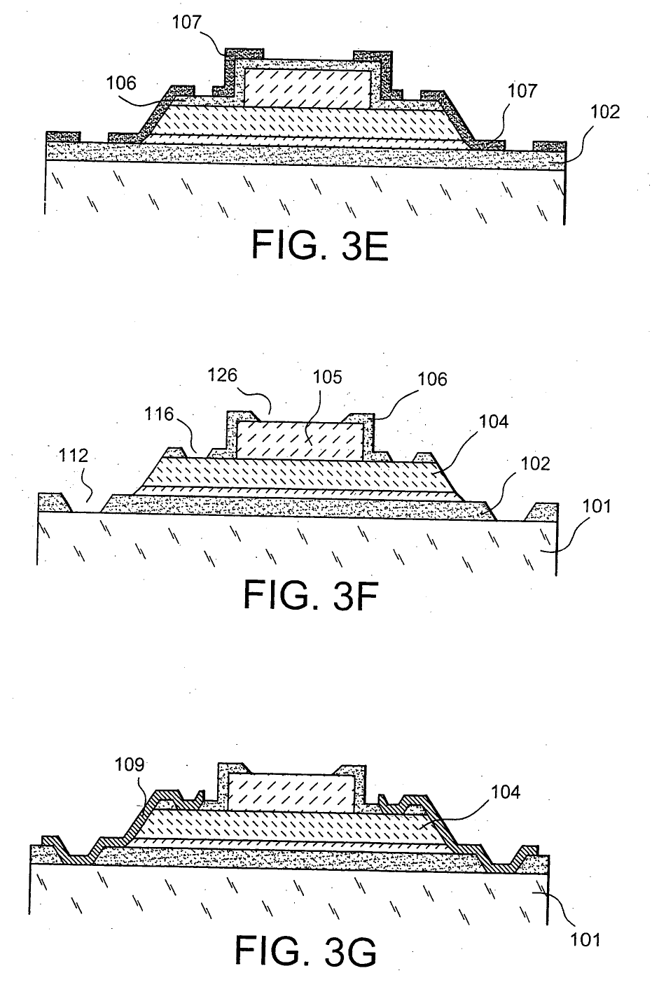

FIGS. 3A to 3J show cross-sectional views illustrating a process for making a power semiconducting device according to the invention. The device made in this example comprises SiC layers epitaxied on an SiC layer transferred onto a silicon support substrate.

FIG. 3A shows a composite substrate 100 formed from a support substrate 101 made of silicon supporting a silicon dioxide layer 102 used to bond a transferred layer of SiC 103. The transferred SiC layer 103 acts as an epitaxy support for the SiC layer 104 and for the SiC layer 105 epitaxied on layer 104.

The n doping of the transferred SiC layer 103 is of the order of 10¹⁷ to 10¹⁹ atoms/cm³ and its thickness is between 0.5 and 1 μm. The doping n of the support substrate 101 is of the order of 10²⁰ atoms/cm³ and its thickness is between 200 and 500 μm. The thickness of the oxide layer 103 is between 2 and 4 μm, for example 2 μm. The support substrate 101 may be overdoped, if necessary at the interface with the silicon dioxide layer 102, before assembly of the composite substrate 100 to facilitate posterior resistive contact (see FIG. 3G).

The SiC layers 104 and 105 on the transferred SiC layer are epitaxied one after the other. Epitaxy is done at below 1410° C. for a support substrate 101 made of silicon.

If the device to be made is a power Schottky diode, the SiC layer 104 is n⁺ doped (doping between 5×10¹⁸ and 5×10²⁰ atoms/cm³) and its thickness is about 4 μm, the SiC layer 105 is n⁻ doped (doping of the order of 10¹⁶ atoms/cm³) and its thickness is about 6 μm. This pair of values is given for a 600 volts type Schottky diode for guidance. These values should be adjusted depending on the required voltage withstand.

FIG. 3B relates to a first lithography level used to define “Mesa” structures by etching of the SiC layer 105 until reaching the SiC layer 104. The “Mesa” structure enables voltage withstand of the component and the fact of exposing the SiC layer 104 will subsequently make it possible to make a resistive contact. Etching may be done by plasma.

The next step consists of depositing an inorganic layer 106, for example a layer of SiO₂ or Si₃N₄ with a thickness of several μm, for example 2 to 4 μm. Among other features, this layer will perform the component passivation function (see FIG. 3C).

FIG. 3D relates to a second lithography level used to define etching areas of layers 106, 104 and 103. This is a first step towards making a contact with the support substrate 101. It is also a means of electrically isolating the component from its neighbours if several components are to be integrated on the same circuit.

When this lithography level has been defined, the layer 106 is etched. In the case of an SiO₂ layer, etching may be done by wet etching in HF solution or by plasma etching. The masking resin is then withdrawn and the SiC layers 104 and 103 are then etched one after the other using the layer 106 as a mask. Etching is done by plasma. The structure obtained is shown in FIG. 3D.

FIG. 3E relates to a third lithography level used to define different openings in layers 102 and 106 for future electrical contacts. FIG. 3E shows the structure obtained after development of the resin layer 107.

The next step is to etch layers 102 and 106 to obtain the structure illustrated in FIG. 3F after removal of the resin. The layer 102 is etched in 112, which will enable subsequent contact to the support substrate 101. The layer 106 is etched in 116, which will enable a future resistive contact. It is also etched in 126 for the future Schottky contact.

FIG. 3G relates to a fourth lithography level useful for making a resistive contact. The deposited metal may be W, Ni or Ti. Its thickness may be between 100 and 500 nm. The deposition may be made by evaporation of cathode sputtering. Lithography defines resistive contact areas with the SiC layer 104 in 116 and also the connection to the resistive contact with the support substrate 101 in 112.

FIG. 3G shows the structure obtained with etching of the deposited metal and removal of the resin. It shows the metallic deposit 109 connecting the SiC layer 104 to the support substrate 101. The metal may be etched conventionally, for example by wet etching for Ni and Ti or by plasma for W. The next step is annealing in order to activate the resistive contact with the SiC in layer 104, within the range between 900 and 1100° C. for Ni and Ti, and within the range between 1000 and 1300° C. for W. The resistive contact with the silicon in the support substrate 101 is activated at the same time.

FIG. 3H relates to a fifth lithography level used to obtain a Schottky contact. Schottky contact metal, either Ti or Ni, is deposited on the previously obtained structure by cathode sputtering or by evaporation, to a thickness of between 100 and 500 nm. The next step is lithography and then etching of this metal so as to form Schottky contact studs 108 on the SiC layer 105. Schottky contact annealing is then applied, for example at a temperature of between 400 and 600° C.

A metallisation layer 117 is deposited on the back face of the support substrate 101 (see FIG. 3I) to make a resistive contact on the back face. This layer may be Al, Ti or Ni. Annealing may be necessary to improve the resistive contact.

Finally, over-metallisation may be necessary to reinforce metallisations on the front face of the device. FIG. 3J shows over-metallisation 118 reinforcing the Schottky contact stud 108 and over-metallisation 119 reinforcing the deposit 109 providing the resistive contact to the SiC layer 104 and the connection to the support substrate 101. This over-metallisation may be aluminium, with a thickness of between 0.5 and 5 μm. FIG. 3J shows the structure obtained after lithography and etching.

A variant of this manufacturing process is possible if doping of the SiC layer 104 is sufficiently high to enable good resistive contact with Ti annealed to about 500° C. The doping required for this purpose is of the order of 5×10¹⁹ atoms/cm³ or more. This doping is possible on the SiC obtained by epitaicy. It is important to note that this doping cannot be obtained on a bulk SiC substrate. However, this is the substrate used to make a resistive contact according to prior art. In the case of this invention, the same metal can be used for the Schottky contact and the resistive contact, with a single annealing at about 500° C.

This variant is used starting from the structure illustrated in FIG. 3F. A single metallic deposit is made, for example of Ti or Ni or a dual layer of one of these metals and another metal. Lithography is done to simultaneously define Schottky studs and resistive contact studs. After etching and annealing at about 500° C., the structure illustrated in FIG. 3H is obtained directly with one complete lithography level less (a deposition, a lithography, an etching and an annealing less). The remainder of the process is identical with metallisation on the back face and possibly over-metallisation.

In order to improve the voltage withstand, it is useful to provide peripheral protections consisting of p doping areas made at the periphery around the Schottky contact. These protections may be made either by local implantation, or by an additional p type epitaxy immediately following the epitaxy of the SiC layer 105, the p layer then being locally etched in the Schottky contact area.

These peripheral protections can be made within the framework of this invention, without any particular difficulty compared with conventional vertical type components. In FIG. 3J, implanted peripheral protections 120 are shown in dashed lines.

The invention can also be used to make a device comprising SiC layers epitaxied on an SiC layer transferred onto an SiC support substrate.

To achieve this, an SiC layer is transferred and bonded using a silicon dioxide layer on an SiC support substrate. The epitaxy is done on the transferred SiC layer. As many SiC layers as necessary are epitaxied. For example, returning to FIG. 3A, the structure is then composed of an SiC support substrate 101, a silicon dioxide layer 102, a transferred SiC layer 103, a first epitaxied SiC layer 104 and a second epitaxied SiC layer 105. The epitaxy may be done at above 1410° C., typically within the range between 1400 and 1600° C. For example, to obtain a Schottky diode, the SiC layer 104 can be n⁺ doped at a doping of 10¹⁹ atoms/cm³ and its thickness may be about 4 μm. The SiC layer 105 may be n⁻ doped at a doping of 10¹⁶ atoms/cm³ and its thickness may be about 6 μm.

The SiC support substrate 101 may be overdoped on the side of the interface with the silicon dioxide layer 102, for example to improve the resistive contact between the metallic deposit 109 and the support substrate 101 (see FIG. 3G). This overdoping may be done before the stacked structure is assembled, by epitaxy or by solid plate implantation or by highly doped polycrystalline or amorphous deposition.

The manufacturing process is similar to that described for the previous device with a silicon support substrate. However, there is a difference for resistive contact on the back face. The metal of the resistive contact on the back face is deposited earlier, at the same time as the resistive contact on the front face SiC. The same annealing is done for resistive contacts on the front face and the back face.

The same variants are applicable as before.

With the invention, a device comprising GaN layers epitaxied on an SiC layer transferred onto an SiC support substrate can also be made.

To achieve this, an SiC layer is transferred and bonded onto an SiC support substrate by means of a silicon dioxide layer. Epitaxy is done on the transferred SiC layer. As many GaN layers as necessary are epitaxied. For example, returning to FIG. 3A, the structure is then composed of an SiC support substrate 101, a silicon dioxide layer 102, a transferred SiC layer 103, a first epitaxied GaN layer 104 and a second epitaxied GaN layer 105. The epitaxy may be done by MOCVD at above 1000° C., typically in the range between 1050 and 1150° C. For example, in order to obtain a GaN Schottky diode, the GaN layer 104 may be n⁺ doped at a doping of 10¹⁹ atoms/cm³ and its thickness may be between about 1 and about 4 μm. The GaN layer 105 may be n⁻ doped at a doping of 10¹⁶ atoms/cm³ and its thickness may be about 6 μm.

An AlN buffer layer may be inserted between the transferred SiC layer and the GaN to improve epitaxial growth.

The SiC support substrate 101 may be overdoped as described above.

In making the device, the technique applied is similar to the cases described above, but with adaptations applicable to resistive contacts and to GaN etching instead of SiC etching.

The invention can also be used to make a device comprising GaN layers epitaxied on an Si {111} layer transferred onto an SiC support substrate.

To achieve this, an SiC layer is transferred and bonded using a silicon dioxide layer onto an SiC support substrate. The epitaxy is done on the transferred layer of Si {111}. As many GaN layers as necessary are epitaxied. For example, returning to FIG. 3A, the structure is then composed of a support substrate 101 made of SiC, a silicon dioxide layer 102, a transferred layer 103 of Si {111}, a first epitaxied GaN layer 104 and a second epitaxied GaN layer 105. The epitaxy may be done by MOCVD at above 1000° C., typically within the range between 1050 and 1150° C. For example, to obtain a GaN Schottky diode, the layers 104 and 105 may be similar to the same layers in the previous example.

An AlN buffer layer may also be inserted between the transferred layer of Si {111} and the GaN to improve epitaxial growth.

The SiC support substrate 101 may be overdoped as described above.

The technique used to make the device is similar to the previous case.

In general, the thin layer of transferred semiconducting material is chosen from among 3C, 4H or 6H polytype SiC, GaN, AlN, Si, ZnO and diamond. The intermediate bonding layer is made of a material chosen from among SiO₂, Si₃N₄ and diamond. The electrically conducting support substrate (monocrystalline or not) is chosen from among SiC, GaN, AlN, Si, GaAs, ZnO and Ge.

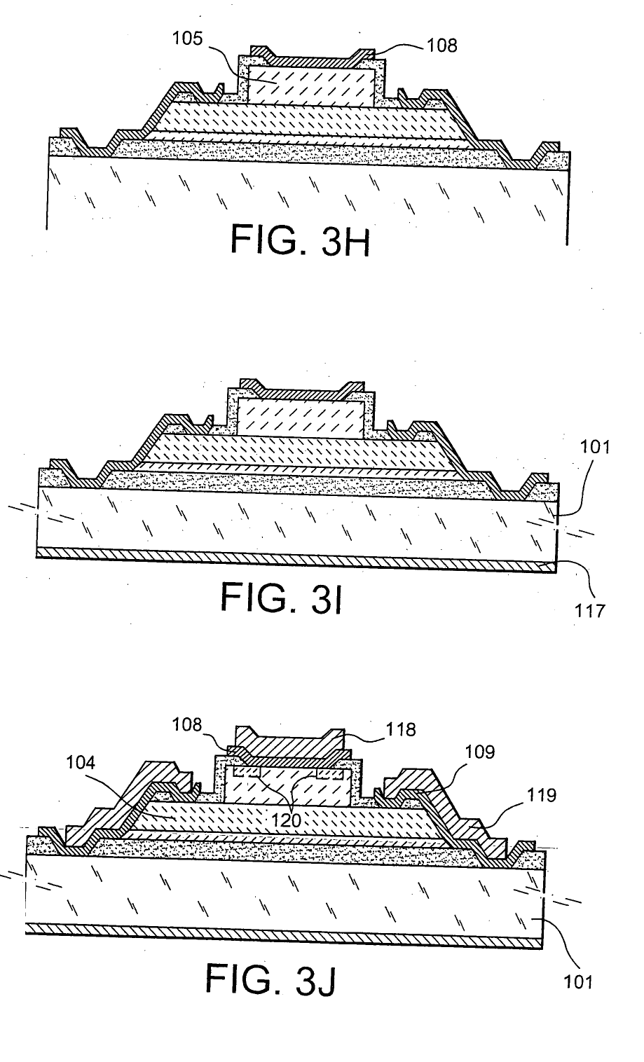

FIG. 4 shows a cross-sectional view of another power semiconducting device according to the invention. This is a PIN type two-pole diode. This device is made on a silicon support substrate 201 supporting a transferred SiC layer 203 fixed to the support substrate by a silicon dioxide layer 202. Several epitaxies are carried out in sequence on the transferred layer 203, consisting of an SiC layer 204, an n⁻ doped SiC layer 205 and a p doped SiC layer 210, in order. The thickness and doping of the SiC layer 205 are adapted to the required voltage withstand, as in the case for conventional vertical PIN diodes. Thus, voltage withstands of the order of 1000 to 5000 V or more can be achieved. The manufacturing process is similar to the manufacturing process for the structures described above, the main difference being the presence of the p type SiC epitaxied layer 210 on which a resistive contact 208 has to be made under the same conditions as on a vertical PIN diode.

The metallisation layer 217 on the back face of the support substrate 201 can be seen in FIG. 4, the metallic deposit 209 making the resistive contact to the SiC layer 204 and the connection to the support substrate 201. The passivation layer 206 can also be seen.

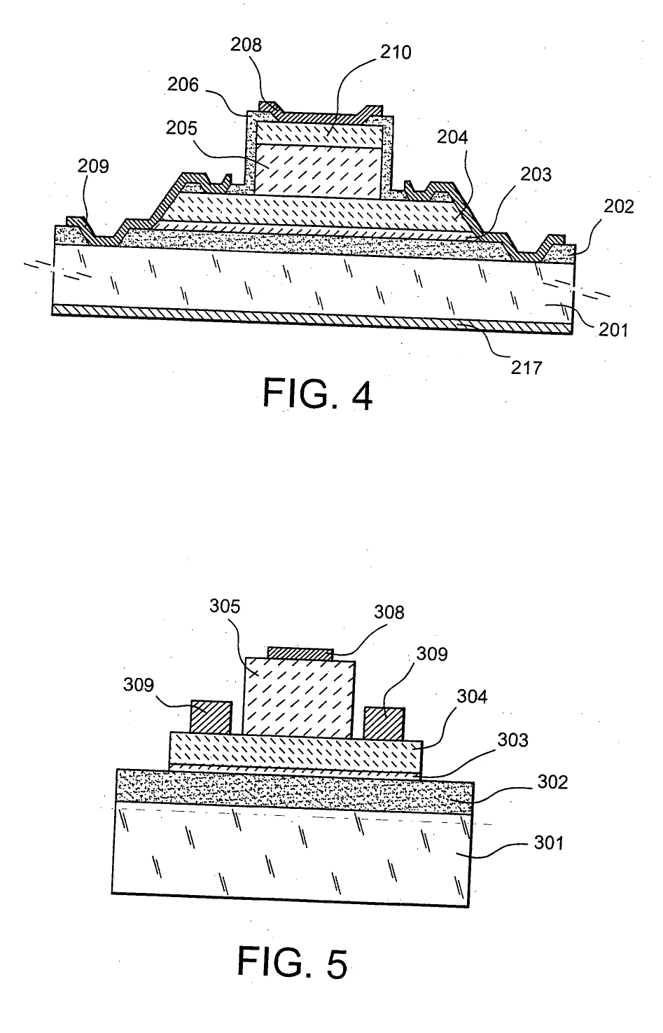

FIG. 5 is a cross-sectional view of a semiconducting device that can be associated with a power semiconducting device according to the invention in order to make an integrated circuit. The characteristics of this type of component are similar to the characteristics of the invention (particularly vertical conduction) but it does not include any contact connection on the back face. The insulating layer on the support substrate is not perforated, so that these components remain electrically isolated from each other: therefore several of them can be integrated with a device according to the invention to form a circuit with conventional contact connections on the front and back faces of the circuit.

FIG. 5 shows a semiconducting support substrate 301 supporting a transferred layer 303 made of a semiconducting material rigidly attached to the support substrate by an electrically insulating layer 302. A semiconducting layer 304 (for example n⁺ doped) and a semiconducting layer 305 (for example n⁻ doped) are epitaxied in sequence on the transferred layer. The layer 305 supports a Schottky contact 308 while the layer 304 supports a resistive contact 309.

1. Power semiconducting device made from a semiconducting material epitaxied on a stacked structure, wherein:
the stacked structure comprises a layer of semiconducting material transferred onto a first face of a support substrate and fixed to the support substrate by an electrically insulating layer, the support substrate comprising electrically conducting means between said first face and a second face, the transferred layer of semiconducting material acting as an epitaxy support for the epitaxied semiconducting material,
means of electrically connecting the device are provided, firstly on the epitaxied semiconducting material, and secondly on the second face of the support substrate, an electrical connection through the electrically insulating layer and said electrically conducting means of the support substrate electrically connecting the epitaxied semiconducting material to the electrically connecting means provided on the second face of the support substrate.

2. Device according to claim 1, wherein the electrically conducting means of the support substrate are composed of the support substrate itself made of an electrically conducting material.

3. Device according to claim 1, wherein the epitaxied semiconducting material comprises several layers with a different doping.

4. Device according to claim 1, wherein the support substrate overdoped on the side of the interface on which the electrically insulating layer is provided.

5. Device according to claim 1, wherein the electrically conducting means of the device comprise at least one Schottky contact.

6. Device according to claim 1, wherein the electrically conducting means of the device comprise at least one resistive contact.

7. Device according to claim 1, wherein the support substrate is made from a semiconducting material.

8. Device according to claim 7, wherein the support substrate is made from a semiconducting material chosen from among SiC, GaN, AlN, Si, GaAs, ZnO and Ge.

9. Device according to claim 1, wherein the material used to make the electrically insulating layer may be chosen from among SiO2, Si3N4 and diamond.

10. Device according to claim 1, wherein the transferred thin layer of semiconducting material is made from a material chosen from among SiC, GaN, AlN, Si, ZnO and diamond.

11. Device according to claim 1, wherein the epitaxied semiconducting material is chosen from among SiC, GaN, AlGaN, InGaN and diamond.

12. Semiconducting circuit, wherein it combines at least one power semiconducting device according to claim 1 and at least one semiconducting device that is not electrically connected to the second face of the support substrate.
